(19) United States
(12) Patent Application Publication
(10) Pub. No.: US 2011/0266045 A1
(43) Pub. Date: Nov. 3, 2011

(54) SHIELD CAN

(75) Inventors: LI-ZHI XIONG, Shenzhen City (CN); LIAN-WEI CHEN, Shenzhen City (CN); YONG CHEN, Shenzhen City (CN); CHENG-RUI LIU, Shenzhen City (CN); LIANG QIU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 12/862,863

(22) Filed: Aug. 25, 2010

(30) Foreign Application Priority Data
Apr. 29, 2010 (CN) 201010159997.7

(51) Int. Cl. H05K 9/00

(52) U.S. Cl. 174/350

(57) ABSTRACT

A shield-can includes a shield member defining a perforated portion to form a peripheral frame and a top plate, the top plate is enabled to be separated from the peripheral frame.

### CROSS-REFERENCE TO RELATED APPLICATIONS

This application is related to a co-pending U.S. Patent Application (Attorney Docket No. US23592), entitled “SHIELD CAN”, by Yong Chen. Such applications have the same assignee as the present application. The above-identified application is incorporated herein by reference.

### BACKGROUND

1. Technical Field

The present disclosure relates to a shield can for a portable electronic device.

2. Description of related art

Electronic components in electronic devices, such as capacitors, can be protected by shield cans from external/internal electromagnetic interferences (EMI). A typical shield can is fixed to and cannot be easily detached from a circuit board. However, to replace or repair the electronic components inside the shield can, the shield can must be detached from the circuit board to expose the electronic components, which may easily result in damage to either or both of the shield can and circuit board.

Therefore, there is room for improvement within the art.

### BRIEF DESCRIPTION OF THE DRAWINGS

Many aspects of the disclosed shield can be better understood with reference to the following drawings. The components in the drawings are not necessarily drawn to scale, the emphasis instead being placed upon clearly illustrating the principles of the exemplary shield can. Moreover, in the drawings, like reference numerals designate corresponding parts throughout the several views.

FIG. 1 is an exploded, schematic view of a shield member and an engaging member according to an exemplary embodiment.

FIG. 2 is a schematic view of the shield member shown in FIG. 1 during a detaching process.

FIG. 3 is an exploded, schematic view of the engaging member shown in FIG. 1 to cover the detached shield member.

FIG. 4 is an assembled schematic view of the shield member covered by the engaging member shown in FIG. 1

### DETAILED DESCRIPTION

The disclosed shield can is suitable for electronic devices, such as mobile phones, personal digital assistants etc.

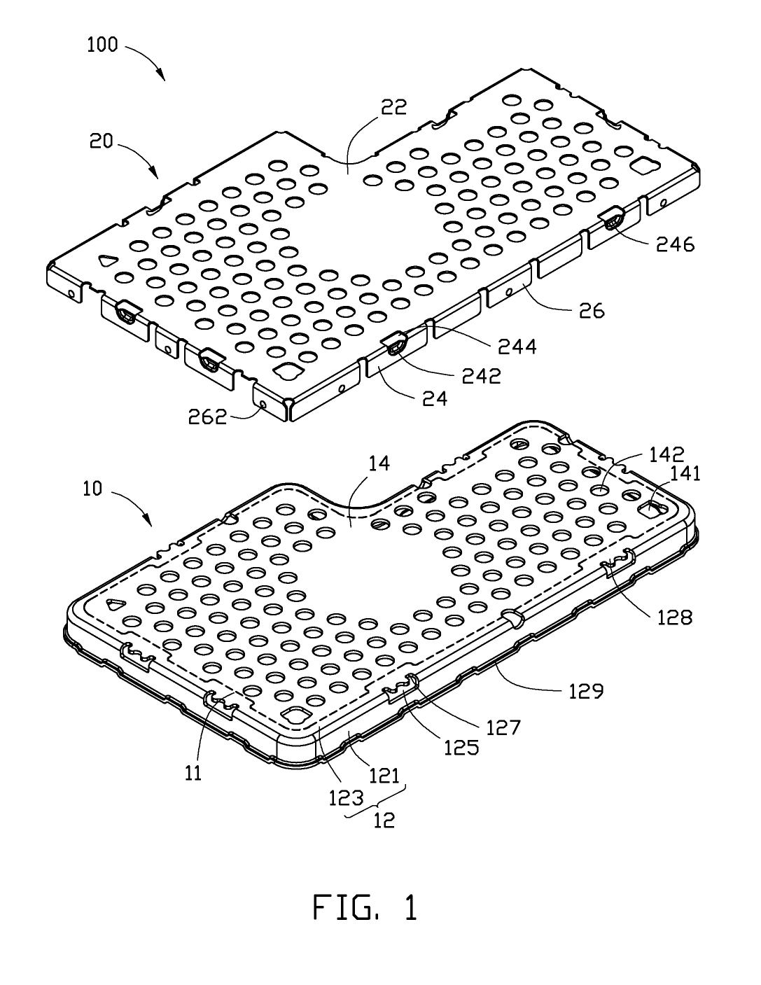

FIG. 1 shows a shield can 100 according to an exemplary embodiment. The shield can 100 is made of metal materials and can be secured on a circuit board to shield electronic components arranged on the circuit board. The shield can 100 includes a shield member 10 and an engaging member 20 detachably engaging with the shield member 10.

The shield member 10 has a peripheral frame 12 and a top plate 14. The top plate 14 covers the top of the peripheral frame 12 and is connected to the peripheral frame 12 by a perforated portion 11. The peripheral frame 12 is an enclosed frame and includes a peripheral wall 121, a top flange 123, and a bottom flange 129. The top flange 123 perpendicularly extends from the inside, top surface of the peripheral wall 121. The bottom flange 129 perpendicularly extends from the outer side, bottom surface of the peripheral wall 121. The peripheral wall 121 and the top flange 123 define spaced latching holes 125, correspondingly defining a latching surface 127 of the top flange 123. The latching surface 127 has an extending flange 128 protruding therefrom. The extending flange 128 is integrally connected to the top flange 123 and parallel with the bottom flange 129. The extending flange 128 is wave shaped and used to latch the engaging member 20. The bottom flange 129 is parallel with the top flange 123 to be connectable to the circuit board.

The perforated portion 11 is formed by a notch through the shield member 10. The perforated portion 11 encloses the top plate 14 and connects to the top flange 123 and the top plate 14. The perforated portion 11 is thinner than the top plate 14, thus, the top plate 14 can be easily detached from the peripheral frame 12, along the perforated portion 11. The top plate 14 defines detaching holes 141 and heat-dissipation holes 142. The detaching holes 141 are defined at corners of the top plate 14 for detaching the top plate 14 using a tool (not shown).

The engaging member 20 includes a main plate 22, first folding flanges 24, and second folding flanges 26. The first folding flanges 24 and the second folding flanges 26 are substantially perpendicularly connected to the peripheral wall of the main plate 22. Each first folding flange 24 has a resisting protrusion 242 recessed for engaging into the latching hole 125 to latch the engaging member 20 to the shield member 10. The first folding flange 24 defines an engaging hole 244 abutting against the resisting protrusion 242, correspondingly forming a resisting surface 246 of the resisting protrusion 242. The engaging hole 244 extends upward to run though the flange of the main plate 22. The engaging hole 244 can receive the extending flange 128 therein to secure the engaging member 20 to the shield member 10. The second folding flanges 26 and the first folding flanges 24 are alternately arranged. Each second folding flange 26 forms a depressed portion 262 recessed into the outer side surface and protruding inward from the internal side surface. The depressed portion 262 is used to resist against the peripheral wall 121 of the peripheral frame 12 to facilitate the latching of the engaging member 20 to the shield member 10.

In use, the shield member 10 is mounted on a circuit board, the bottom flange 129 can be secured to the circuit board by, for example, soldering. Thus, the electronic components fixed on the circuit board can be received in and shielded from EMI by the shield member 10.

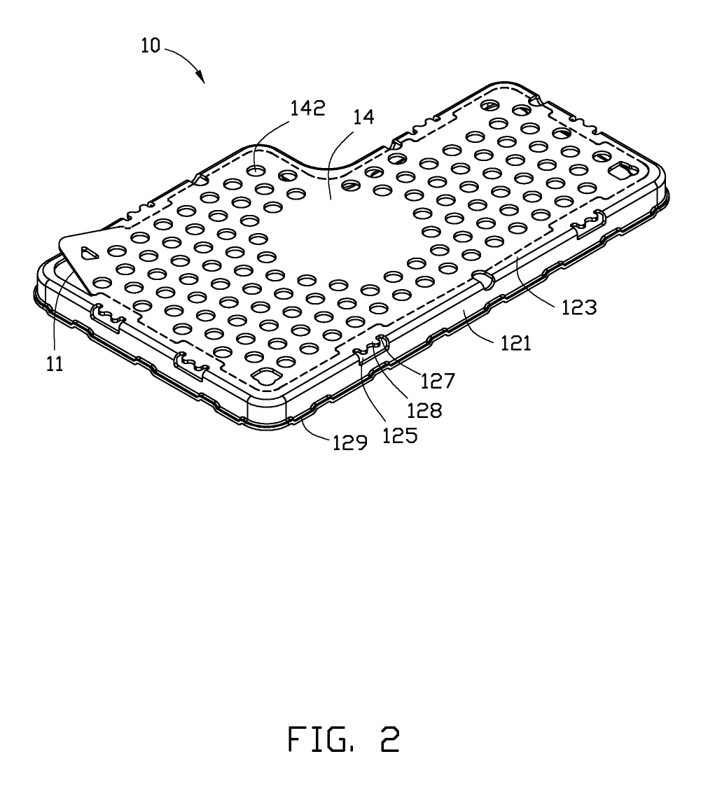

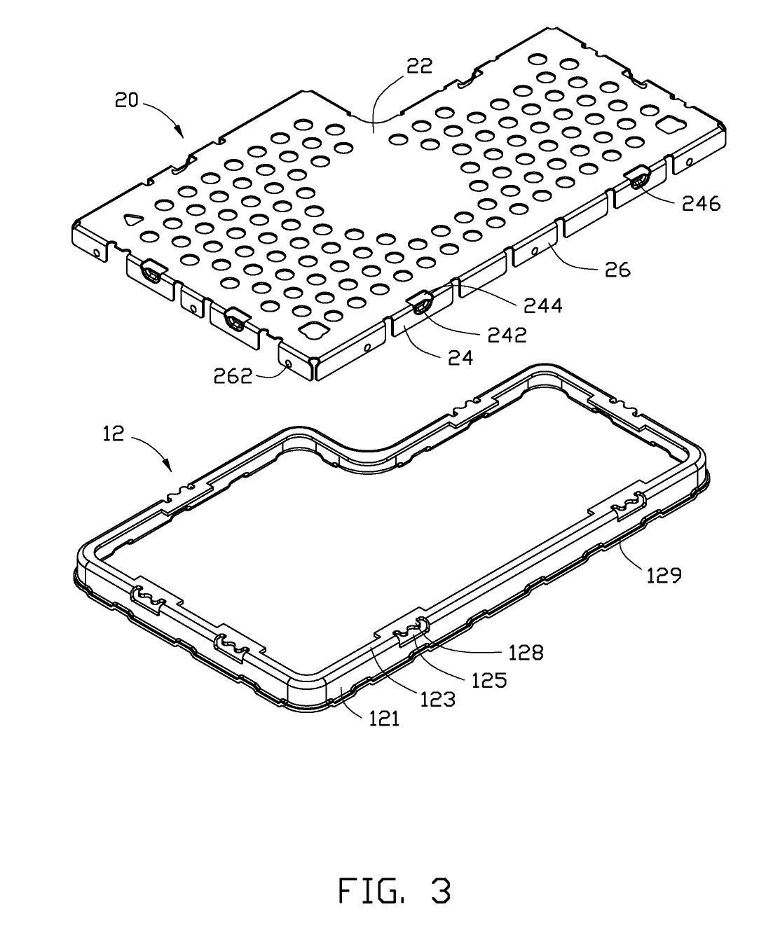

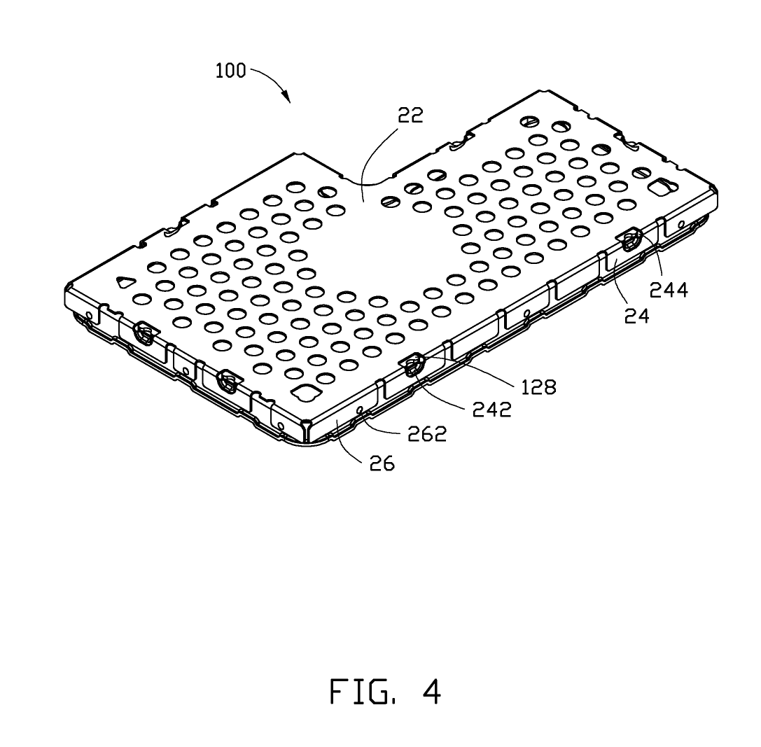

Referring to FIG. 2 to FIG. 4, to repair the electronic components, a tool can be extended into one of the detaching holes 141 to hook and lift the top plate 14. The tool may be pulled upward to detach the top plate 14 from the peripheral frame 12 along the perforated portion 11. Thus, electronic components are exposed for repair. After the electronic components are repaired, the engaging member 20 is engaged on the peripheral frame 12 to once again shield the repaired electronic components. The engaging member 20 is pressed downward on the peripheral frame 12, and the resisting protrusions 242 latch into the latching holes 125 and the extending flanges 128 latch into the engaging hole 244. The extending flange 128 is clamped tightly between the main plate 22 and the resisting surface 246 of the first folding flange 24.

It is understood that the engaging member 20 can be assembled on the shield member 10 before detaching the top plate 14. To repair electronic components, the engaging member 20 can be taken from the shield member 10 before detaching the top plate 14.

It is to be understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A shield can, comprising:
a shield member defining a perforated portion to form a peripheral frame and a top plate, the top plate being enable to be separated from the peripheral frame along the peripheral frame;
an engaging member detachably engaging with the shield member, wherein: when the top plate is detached from the shield member, the engaging member latches with the peripheral frame and acts as the top plate.

2. The shield can as claimed in claim 1, wherein the peripheral frame includes a peripheral wall, a top flange perpendicularly extending at the top of the peripheral wall, and a bottom flange perpendicularly extending at the bottom of the peripheral wall, the top flange connects to the perforated portion and the bottom flange is for assembly of the periphery.

3. The shield can as claimed in claim 2, wherein the peripheral wall defines latching holes, each latching hole extends to the top flange to correspondingly form a latching surface on the top flange.

4. The shield can as claimed in claim 3, wherein the latching surface protrudes an extending flange, the extending flange is wave shaped and parallel with the bottom flange.

5. The shield can as claimed in claim 3, wherein the perforated portion is formed by defining a perforated on the shield member and encloses the top plate, the perforated portion connects to the top flange and the top plate, and is thinner than the top plate.

6. The shield can as claimed in claim 4, wherein the engaging member includes a main plate, first folding flanges and second folding flanges, the first folding flanges and the second folding flanges are perpendicularly formed at the periphery of the main plate.

7. The shield can as claimed in claim 6, wherein each first folding flange has a resisting protrusion to engage into the latching hole to latch the engaging member with the shield member.

8. The shield can as claimed in claim 7, wherein the first folding flange defines an engaging hole abutting against the resisting protrusion, the engaging hole receive the extending flange therein to securely latch the engaging member with the shield member.

9. The shield can as claimed in claim 6, wherein the second folding flange forms a depressed portion to resist against the peripheral wall of the peripheral frame.

10. The shield can as claimed in claim 6, wherein the top plate defines detaching holes and heat-dissipation holes, the detaching holes is used for detaching the top plate, the heat-dissipation holes is used for passing of the heat.

11. A shield can, comprising:
a shield member defining a perforated portion to form a peripheral frame and a top plate, the top plate being enable to be separated from the peripheral frame along the perforated portion.

12. The shield can as claimed in claim 11, wherein the shield can includes an engaging member detachably engaging with the shield member.

13. The shield can as claimed in claim 12, wherein the peripheral frame includes a peripheral wall, a top flange perpendicularly extending at the top of the peripheral wall, and a bottom flange perpendicularly extending at the bottom of the peripheral wall, the top flange connects to the perforated portion and the bottom flange is for assembly of the periphery.

14. The shield can as claimed in claim 13, wherein the peripheral wall defines latching holes, each latching hole extends to the top flange to correspondingly form a latching surface on the top flange.

15. The shield can as claimed in claim 14, wherein the latching surface protrudes an extending flange, the extending flange is wave shaped and parallel with the bottom flange.

16. The shield can as claimed in claim 14, wherein the perforated portion is formed by defining a perforated on the shield member and encloses the top plate, the perforated portion connects to the top flange and the top plate, and has a smaller thickness than the top plate.

17. The shield can as claimed in claim 15, wherein the engaging member includes a main plate, first folding flanges and second folding flanges, the first folding flanges and the second folding flanges are perpendicularly formed at the periphery of the main plate.

18. The shield can as claimed in claim 17, wherein each first folding flange has a resisting protrusion to engage into the latching hole to latch the engaging member with the shield member.

19. The shield can as claimed in claim 18, wherein the first folding flange defines an engaging hole abutting with the resisting protrusion, the engaging hole receive the extending flange therein to securely latch the engaging member with the shield member.

20. The shield can as claimed in claim 17, wherein the second folding flange forms a depressed portion to resist against the peripheral wall of the peripheral frame.
